(19) United States
(12) Patent Application Publication
(10) Pub. No.: US 2025/0275278 A1
(43) Pub. Date: Aug. 28, 2025

(54) IMAGE SENSING STRUCTURE AND MANUFACTURING METHOD THEREOF

(71) Applicant: Taiwan Semiconductor Manufacturing Company, Ltd., Hsinchu (TW)

(72) Inventors: Keng-Yu Chou, Kaohsiung City (TW); Chun-Hao Chuang, Hsinchu City (TW); Wen-Hau Wu, New Taipei City (TW); Cheng-Yu Huang, Hsinchu (TW); Yi-Hsuan Wang, Hsinchu City (TW); Wei-Chieh Chiang, Yuanlin Township (TW); Chih-Kung Chang, Zhudong Township (TW)

(21) Appl. No.: 18/749,921

(22) Filed: Jun. 21, 2024

Related U.S. Application Data
(60) Provisional application No. 63/558,144, filed on Feb. 27, 2024.

(51) Int. Cl. H01L 27/146

(52) U.S. Cl. CPC H10F 39/807; H10F 39/024; H10F 39/182; H10F 39/8037; H10F 39/8053

(57) ABSTRACT

The present disclosure provides an image sensing structure. The image sensing structure includes: a first pixel and a second pixel. The first pixel includes a first photodiode, a second photodiode, and a first isolation member. The first isolation member is disposed between the first photodiode and the second photodiode and extends along a first direction. The second pixel is disposed adjacent to the first pixel and includes a third photodiode, a fourth photodiode, and a second isolation member. The second isolation member is disposed between the third photodiode and the fourth photodiode and extends along a second direction substantially perpendicular to the first direction.

### REFERENCE TO RELATED APPLICATION

This Application claims the benefit of U.S. Provisional Application number 63/558, 144, filed Feb. 27, 2024, the contents of which are hereby incorporated by reference in their entirety.

### BACKGROUND

CMOS image sensors are used in many types of electronic devices, such as video cameras and digital cameras to, capture images.

As technological standards advance, there is an ever-increasing consumer demand for image-sensing devices that occupy less space, consume less power, and produce higher-quality images at greater speeds. As a result, there remains a need to develop a CMOS image sensor with an improved structure.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a schematic top view of a portion of an image sensing structure, in accordance with some embodiments of the present disclosure.

FIG. 2 is a schematic cross-sectional view of a portion of the image sensing structure along a line AA′ in FIG. 1, in accordance with some embodiments of the present disclosure.

FIG. 3 is a schematic cross-sectional view of a portion of the image sensing structure along a line BB′ in FIG. 1, in accordance with some embodiments of the present disclosure.

FIG. 4 is a schematic top view showing a color filter array (CFA) of another image sensing structure, in accordance with some embodiments of the present disclosure.

FIGS. 5A and 5B are enlarged top views of portions R10 and R20 of FIG. 4, respectively, in accordance with some embodiments of the present disclosure.

FIG. 6A is a schematic cross-sectional view of the portion R10 along a line CC′ in FIG. 4, in accordance with some embodiments of the present disclosure.

FIG. 6B is a schematic perspective view of FIG. 6A, in accordance with some embodiments of the present disclosure.

FIG. 7A is a schematic cross-sectional view of the portion R20 along a line DD′ in FIG. 4, in accordance with some embodiments of the present disclosure.

FIG. 7B is a schematic perspective view of FIG. 7A, in accordance with some embodiments of the present disclosure.

FIGS. 8 to 10 are schematic perspective views of various portions R30, R40 and R50 of FIG. 4, in accordance with some embodiments of the present disclosure.

FIG. 11 is a schematic top view showing a CFA of another image sensing structure, in accordance with some embodiments of the present disclosure.

FIG. 12A is a schematic cross-sectional view of a portion R60 along a line EE′ in FIG. 11, in accordance with some embodiments of the present disclosure.

FIG. 12B is a schematic perspective view of FIG. 12A, in accordance with some embodiments of the present disclosure.

FIG. 13A is a schematic cross-sectional view of a portion R70 along a line FF′ in FIG. 11, in accordance with some embodiments of the present disclosure.

FIG. 13B is a schematic perspective view of FIG. 13A, in accordance with some embodiments of the present disclosure.

FIGS. 14 and 15 are schematic perspective views of portions R80 and R90 of FIG. 11, respectively in accordance with some embodiments of the present disclosure.

FIG. 16 is a schematic top view showing a CFA of another image sensing structure, in accordance with some embodiments of the present disclosure.

FIG. 17 is a schematic top view showing a CFA of another image sensing structure, in accordance with some embodiments of the present disclosure.

FIG. 18A is an enlarged view of a portion R120 of the image sensing structure of FIG. 17, in accordance with some embodiments of the present disclosure.

FIGS. 18B and 18C are schematic cross-sectional and perspective views of FIG. 18A, in accordance with some embodiments of the present disclosure.

FIGS. 19A and 19B are schematic cross-sectional and perspective views of another portion R130 of the image sensing structure of FIG. 17, in accordance with some embodiments of the present disclosure.

FIG. 20 is a flow diagram showing a method for forming an image sensing structure, in accordance with some embodiments of the present disclosure.

FIGS. 21 to 27 are schematic cross-sectional or top views illustrating sequential operations of the method in FIG. 20, in accordance with some embodiments of the present disclosure.

FIG. 28 is a schematic perspective view illustrating a combination of two image sensing structures, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In some embodiments, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass orientations of the device in use or operation in some embodiments different from the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” and “about” generally mean within a value or range which can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

A CMOS image sensor can be designed as having multiple dual photodiodes (DPDs) arranged as an array. The dual photodiode can absorb more light than a single photodiode of having the same number of pixels. Therefore, the dual photodiode can provide a more efficient mechanism to generate photo-induced charges. The CMOS image sensor with DPDs can reduce noise and capture images with vibrant colors.

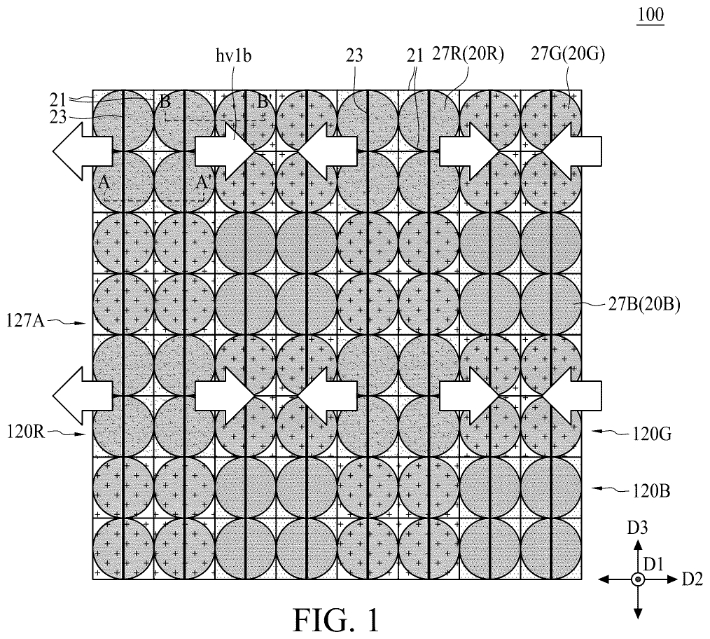

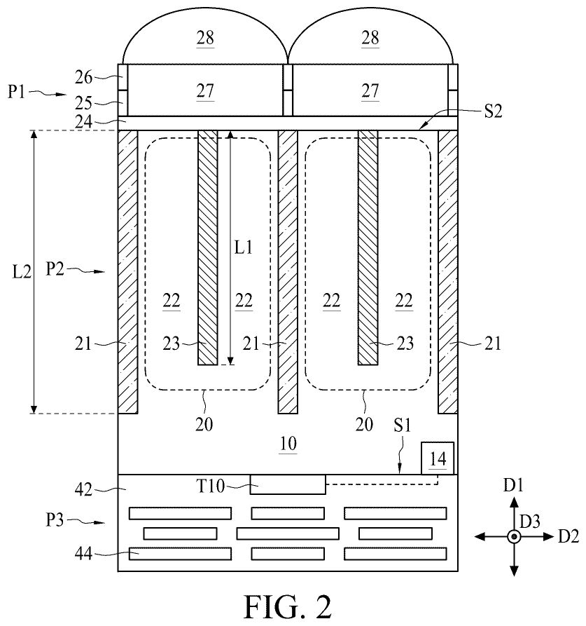

FIG. 1 is a schematic top view of a portion of an image sensing structure 100, and FIG. 2 is a schematic cross-sectional view of a portion of the image sensing structure 100 along a line AA′ in FIG. 1. In some embodiments, the image sensing structure 100 is an image sensing device or a portion of the image sensing device. The image sensing structure 100 is, for example, a backside illumination (BSI) image sensing structure. FIG. 1 illustrates the portion of the image sensing structure 100 in a color filter array (CFA) 127A. In some embodiments, the image sensing structure 100 includes an optical portion P1, a pixel portion P2 and a circuitry portion P3. The pixel portion P2 is between the optical portion P1 and the circuitry portion P3. The pixel portion P2 includes a substrate 10 having a first surface S1 and a second surface S2 opposite to the first surface S1. The substrate 10 includes any type of semiconductor body such as a silicon wafer or one or more dies on a wafer, as well as any other type of semiconductor and/or epitaxial layers formed thereon and/or otherwise associated therewith. In some embodiments, the substrate 10 is doped with p-type impurities and thus forms a p-type substrate.

Several isolation structures 21 are disposed within the substrate 10. In some embodiments, the isolation structure 21 is a deep trench isolation (DTI) structure. In some embodiments, the isolation structure 21 extends along a first direction D1 between the first surface S1 and the second surface S2 of the substrate 10. In some embodiments, the isolation structure 21 extends from the second surface S2 toward a predetermined depth of the substrate 10. In some embodiments, the first direction D1 is a direction along a thickness of the substrate 10 or a height of the image sensing structure 100. The isolation structure 21 is formed of, for example, oxide, nitride, a high-k dielectric material such as aluminum oxide (AlO), tantalum oxide (TaO), hafnium oxide (HfO), hafnium silicon oxide (HfSiO), hafnium aluminum oxide (HfAO), hafnium tantalum oxide (HfTaO), or a combination thereof.

The isolation structures 21 divide the substrate 10 into multiple pixel regions 20. In some embodiments, the isolation structures 21 and the pixel regions 20 are alternately arranged along a second direction D2 perpendicular to the first direction D1. As such, the isolation structure 21 may be referred to as an inter-pixel DTI structure. The isolation structure 21 extends along a third direction D3 (i.e., into the paper of FIG. 2) perpendicular to the first direction D1 and the second direction D2.

In some embodiments, the pixel region 20 is formed by providing doping impurities to the substrate 10, wherein the doping impurities have a conductivity type opposite to a conductivity type of the substrate 10. In some embodiments, the pixel region 20 is doped with n-type impurities. Due to their opposite types of dopants, a P-N junction is formed between the substrate 10 and the pixel region 20. Therefore, each pixel region 20 includes a P-N junction. The P-N junction includes a photodiode. In some embodiments, the pixel region 20 is a light sensing layer. The isolation structure 21 is used to optically isolate the pixel region 20 from an adjacent pixel region 20.

Several isolation members 23 are disposed within the substrate 10. The isolation member 23 is formed of a material different from or same as a material of the isolation structure 21. In some embodiments, the isolation member 23 extends along the first direction D1 between the first surface S1 and the second surface S2 of the substrate 10. In some embodiments, the isolation member 23 extends from the second surface S2 of the substrate 10 toward a predetermined depth of the substrate 10. In some embodiments, a length L1 of the isolation member 23 is substantially less than a length L2 of the isolation structure 21, as shown in FIG. 2. In other embodiments, the length L1 of the isolation member 23 is substantially equal to or greater than the length L2 of the isolation structure 21. In some embodiments, the isolation member 23 is parallel to the isolation structure 21 along the third direction D3.

In some embodiments, the isolation member 23 is disposed within each pixel region 20 and surrounded by the isolation structures 21. The isolation member 23 divides the pixel region 20 into at least two photodiode regions 22. Two photodiode regions 22 in one pixel region 20 are referred to as a dual photodiode (DPD). As such, the isolation member 23 is referred to as an in-pixel DTI structure.

The photodiode region 22 is used to convert radiation that enters into the substrate 10 from the second surface S2 of the substrate 10 to an electrical signal. When incident light (containing photons of sufficient energy) strikes the photodiode region 22, an electron-hole pair is created.

In some embodiments, the optical portion P1 includes an anti-reflection layer 24, multiple metal grids 25, one or more dielectric layers 26, multiple color filters 27 and multiple microlenses 28. The anti-reflection layer 24 is disposed on the second surface S2 of the substrate 10. In some embodiments, the anti-reflection layer 24 is formed of oxide, nitride, a high-k dielectric material such as aluminum oxide (AlO), tantalum oxide (TaO), hafnium oxide (HfO), hafnium silicon oxide (HfSiO), hafnium aluminum oxide (HfAlO), hafnium tantalum oxide (HfTaO), or a combination thereof. The anti-reflection layer 24 is used to minimize light reflection and thus allow more light to reach the pixel portion P2.

In some embodiments, the metal grids 25 are disposed on the anti-reflection layer 24 and are aligned with the isolation structures 21, respectively. The metal grids 25 are formed of tungsten (W), copper (Cu) or aluminum copper (AlCu). The metal grids 25 can be used to reduce optical interference of one pixel region 20 from an adjacent pixel region 20. The metal grids 25 are used to reflect the refracted light or reflected light back to the color filters 27, and thus the optical isolation among adjacent pixels can be improved.

The color filters 27 are disposed on the anti-reflection layer 24 and are near the metal grids 25. Adjacent pairs of color filters 27 are separated by one metal grid 25. Space over the metal grids 25 is filled with the dielectric layer 26 made of oxide. The color filters 27 are separated from the substrate 10 or the pixel region 20 by the anti-reflection layer 24.

In other embodiments, the dielectric layer 26 is disposed on the anti-reflection layer 24. In such embodiments, the metal grids 25 are separately embedded in the dielectric layer 26 and are aligned with the isolation structures 21. That is, the dielectric layer 26 separates the metal grids 25 from the substrate 10. The color filters 27 are surrounded by the dielectric layer 26, and top surfaces of the color filters 27 are coplanar with or below a top surface of the dielectric layer 26.

In some embodiments, the color filter 27 is aligned with the pixel region 20. The color filter 27 is disposed over two photodiode regions 22 and an isolation member 23 between the two photodiode regions 22. Such arrangement can increase radiation of incident light onto the pixel region 20. The color filter 27 is used to allow light or radiation having a wavelength within a specific range to pass. For example, a color filter 27 used to transmit incident light with a wavelength between about 620 nanometers (nm) and about 750 nm (i.e., red light) is referred to as a red filter 27R. A color filter 27 used to transmit incident light with a wavelength between about 495 nm and about 570 nm (i.e., green light) is referred to as a green filter 27G. A color filter 27 used to transmit incident light with a wavelength between about 450 nm and about 495 nm (i.e., blue light) is referred to as a blue filter 27B. The red, green and blue filters 27R, 27G and 27B are illustrated in the figures and described below.

In some embodiments, the microlens 28 is disposed on the color filter 27 and portions of the dielectric layer 26. The microlens 28 has a curved surface (or convex surface) that directs an incoming light beam and facilitates condensation of the light beam. The microlens 28 is aligned with the color filter 27 and the pixel region 20. Such arrangement can increase the radiation of the light beam onto the pixel region 20. Since the photodiode regions 22 are formed as a pair in a single pixel region 20, one color filter 27 is disposed over two photodiode regions 22, and one microlens 28 is disposed over two photodiode regions 22.

In some embodiments, the circuitry portion P3 includes one or more transistors T10, one or more interlayer dielectric (ILD) layers 42 and multiple conductive lines 44. The transistor T10 is disposed on the first surface S1 of the substrate 10 and is surrounded by the ILD layer 42. The conductive lines 44 are interconnected and embedded in the ILD layer 42. The ILD layer 42 is formed of oxide or a suitable material. The conductive lines 44 are formed of a metal or an alloy.

Although not specifically illustrated in FIG. 2, the transistor T10 includes a transfer transistor serving as a transfer gate, a reset transistor serving as a reset gate, a source follower transistor serving as a source follower gate (an amplification gate), and a selection transistor serving as a selection gate. Some or all of the transistors are disposed in the circuitry portion P3. In some embodiments, a floating node (or a floating diffusion region) 14 is disposed in the pixel portion P2.

In some embodiments, the floating node 14 is used to store the charges that are transferred and generated from the pixel regions 20. The charges stored in the floating node 14 are then converted into a voltage signal. Multiple pixel regions 20 can measure different components of the light beam based on multiple voltage signals converted by the floating node 14. The voltage signals can be read or processed by the circuitry portion P3 of the image sensing structure 100. Therefore, a measurement result for generation of a 2D or 3D image of a scene can be provided by the image sensing structure 100.

As illustrated in FIG. 1, all of the isolation members 23 extend along the third direction D3. In some embodiments, the isolation members 23 are perpendicular to some of the isolation structures 21. The CFA 127A can separate various colors from a color image. A resulting output from the image sensing structure 100 with the CFA 127A can be interpolated to form a full-color image. In some embodiments, the CFA 127A is an arrangement of red filters 27R, green filters 27G and blue filters 27B formed in a square over image sensing structures (i.e., the photodiode regions 22). The red, green and blue filters 27R, 27G and 27B respectively allow incident light with a wavelength within a specific range to pass. The pixel region 20 corresponding to the red filter 27R is a red pixel region 20R (or, simply, a red pixel), the pixel region 20 corresponding to the green filter 27G is a green pixel region 20G (or, simply, a green pixel), and the pixel region 20 corresponding to the blue filter 27B is a blue pixel region 20B (or, simply, a blue pixel). Every four red pixel regions 20R form a 2×2 red pixel unit 120R, every four green pixel regions 20G form a 2×2 green pixel unit 120G, and every four blue pixel regions 20B form a 2×2 blue pixel unit 120B.

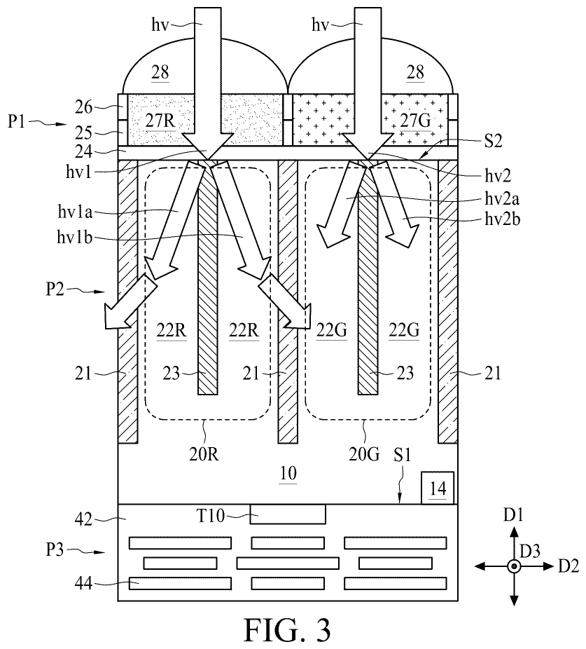

FIG. 3 is a schematic cross-sectional view of a portion of the image sensing structure 100 along a line BB′ in FIG. 1. FIG. 3 is used to illustrate an operational principle of the image sensing structure 100. In some embodiments, a light beam hv is incident on the second surface S2 of the substrate 10 via, in sequence, the microlens 28, the red filter 27R/the green filter 27G, and the anti-reflection layer 24. A first light beam hv1 (i.e. red light in the light beam hv) can pass through the red filter 27R, and a second light beam hv2 (i.e. green light in the light beam hv) can pass through the green filter 27G. After passing through the red filter 27R, the first light hv1 beam splits into at least two red light beams hv1a and hv1b. After passing through the green filter 27G, the second light beam hv2 splits into at least two green light beams hv2a and hv2b. The photodiode regions 22 in FIG. 2 corresponding to the red filter 27R, the green filter 27G and the blue filter 27B are respectively denoted as photodiode regions 22R, photodiode regions 22G, and photodiode regions 22B. The red light beams hv1a and hv1b then interact with the photodiode regions 22R. The green light beams hv2a and hv2b then interact with the photodiode regions 22G. Thus, multiple photo-induced carriers (e.g., electrons) are generated and collected by the photodiode regions 22R and 22G, and the photo-induced carriers are then transferred from the pixel regions 20R and 20G to the floating node 14.

The circuitry portion P3 processes signals generated from the photo-induced carriers in the pixel portion P2, and performs any suitable operations based on such signals.

The isolation structures 21 are used to reflect the refracted light or reflected light back to the pixel regions 20, and thus a full-well capacity of the image sensing structure 100 can be increased and optical isolation of adjacent pixels is thus improved.

However, in some cases, the red light beams hv1a and hv1b may not travel straight along the substrate 10 from the second surface S2 toward the first surface S1 due to their diffraction behavior. Light with longer wavelengths has a greater tendency to diffract or penetrate an obstacle. Accordingly, light with longer wavelengths can reach greater depths of the substrate 10. The red light beams hv1a and hv1b tend to penetrate the isolation structures 21 and reach other adjacent pixel regions 20. Therefore, despite the use of the isolation structures 21, some red light (such as the red light beams hv1a and hv1b) illuminates, for example, adjacent photodiode regions 22G. Such phenomenon is referred to as “crosstalk”. The red light beams hv1a and hv1b penetrating the isolation structures 21 cause some of the photodiode regions 22G illuminated by such red light beams hv1a and hv1b to produce more photo-induced carriers.

Referring to FIGS. 1 and 3, the red light beams hv1a and hv1b (represented by arrows) penetrating respective neighboring photodiode regions 22G cause some green pixel units 120G to be brighter. The other green pixel units 120G not affected by any red light (i.e., the green pixel units 120G not pointed to by any arrow) is relatively darker. Such problem causes uneven brightness of pixels of the image sensing structure 100.

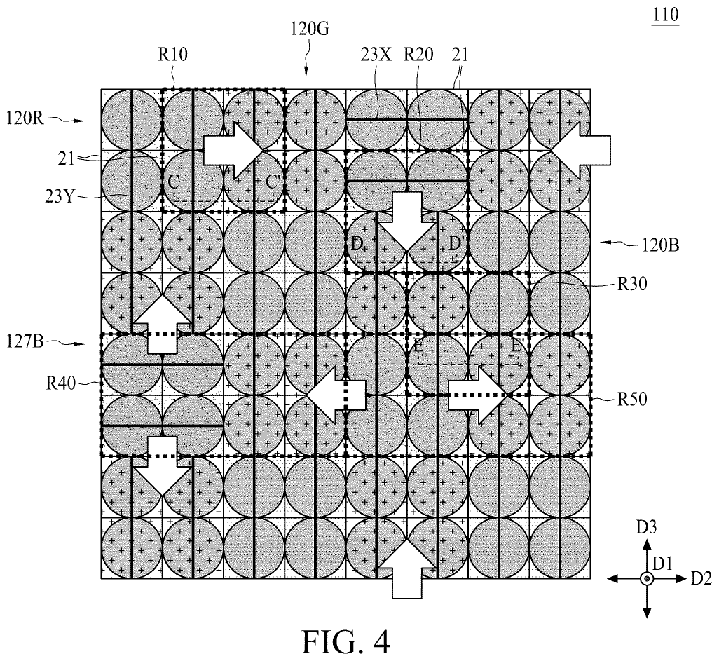

FIG. 4 is a schematic top view showing a CFA 127B of another image sensing structure 110. The image sensing structure 110 is similar to the image sensing structure 100, except the image sensing structure 110 has different orientations of isolation members 23. In some embodiments, the image sensing structure 110 includes multiple first isolation members 23X extending along the second direction D2 and multiple second isolation members 23Y extending along the third direction D3. The first isolation member 23X is perpendicular to the second isolation member 23Y from the top view.

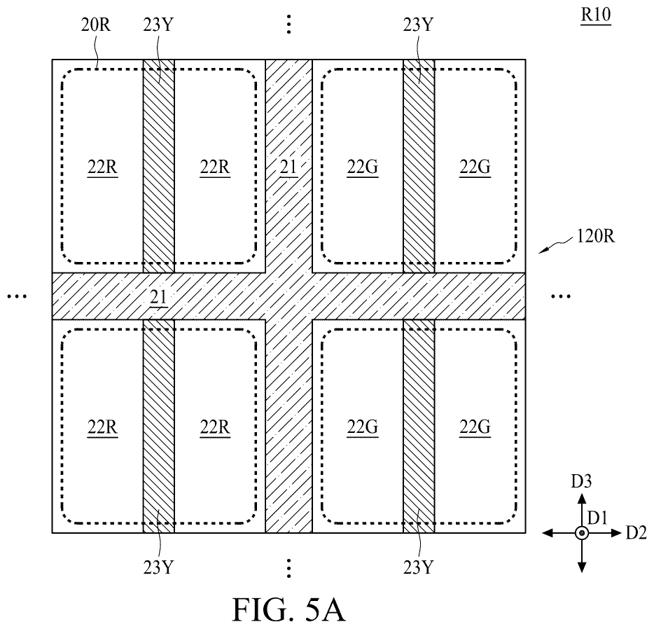

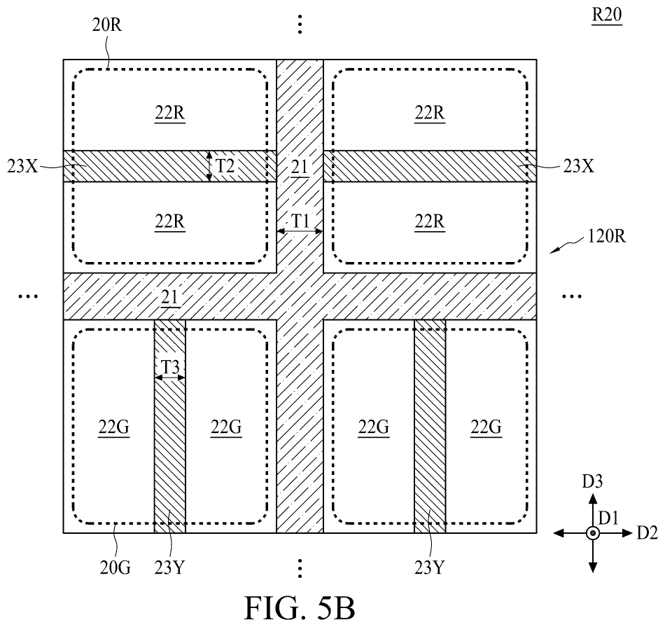

FIGS. 5A and 5B are enlarged top views of portions R10 and R20 of FIG. 4, respectively. Some elements are not shown for clarity. Referring to FIG. 5A, the portion R10 is a red pixel unit 120R including two red pixel regions 20R and two green pixel regions separated by two isolation structures 21 perpendicular to each other. In some embodiments, the red pixel unit 120R includes four second isolation members 23Y extending along the third direction D3 and no first isolation member 23X extending along the second direction D2 is present. The second isolation member 23Y separates two photodiode regions 22R in each red pixel region 20R. The second isolation member 23Y is between the two photodiode regions 22R in each red pixel region 20R. In some embodiments, the second isolation member 23Y is connected to the isolation structure 21.

Referring to FIG. 5B, the portion R20 includes two red pixel regions 20R and two green pixel regions 20G separated by two isolation structures 21 perpendicular to each other. In some embodiments, the portion R20 includes two first isolation members 23X extending along the second direction D2. The first isolation member 23X separates two photodiode regions 22R in each red pixel region 20R. The first isolation member 23X is between the two photodiode regions 22R in each red pixel region 20R. In some embodiments, the first isolation member 23X is connected to the isolation structure 21. In some embodiments, the portion R20 includes two second isolation members 23Y extending along the third direction D3. The second isolation member 23Y separates two photodiode regions 22G in each green pixel region 20G. The second isolation member 23Y is between the two photodiode regions 22G in each green pixel region 20G. In some embodiments, the second isolation member 23Y is connected to the isolation structure 21. In some embodiments, a thickness T1 of the isolation structure 21 is substantially equal to or greater than a thickness T2 of the first isolation member 23X or a thickness T3 of the second isolation member 23Y. In some embodiments, the thickness T2 of the first isolation member 23X is substantially equal to the thickness T3 of the second isolation member 23Y.

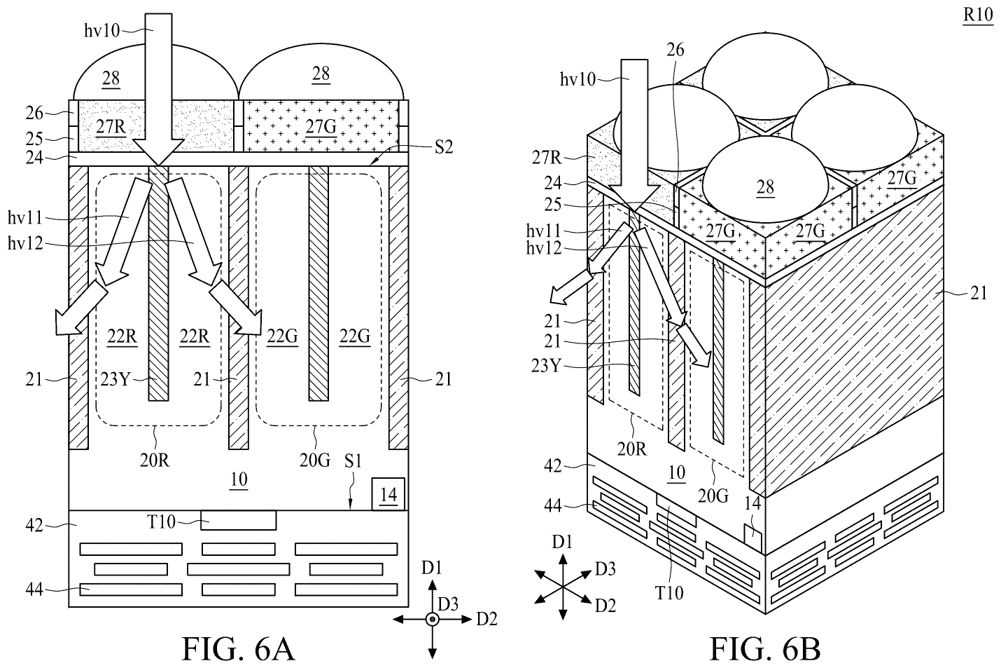

FIG. 6A is a schematic cross-sectional view of the portion R10 along a line CC′ in FIG. 4. FIG. 6B is a schematic perspective view of the portion R10 in FIG. 6A. The isolation structures 21, the first isolation members 23X and the second isolation members 23Y are embedded in the substrate 10. The isolation structures 21, the first isolation members 23X and the second isolation members 23Y are strips of walls, as shown in FIG. 6B. For convenience of illustration, only portions of the isolation structures 21 are shown in the perspective views referred to below.

Similar to the principle discussed above in reference to FIG. 3, when an incident light beam hv10 passes through the microlens 28, the red filter 27R and the anti-reflection layer 24, the incident light beam hv10 is split into at least two red light beams hv11 and hv12 by the second isolation member 23Y. The red light beams hv11 and hv12 may penetrate neighboring photodiode regions 22G in the green pixel region 20G on opposite sides of the isolation structure 21. Therefore, portions of the green pixel region 20G accepting the additional red light beams (such as hv11 and hv12) will appear brighter. Referring to FIG. 4, a portion of the green pixel unit 120G at the right of the portion R10 (near the arrow) will appear brighter than the rest portion of the green pixel unit 120G.

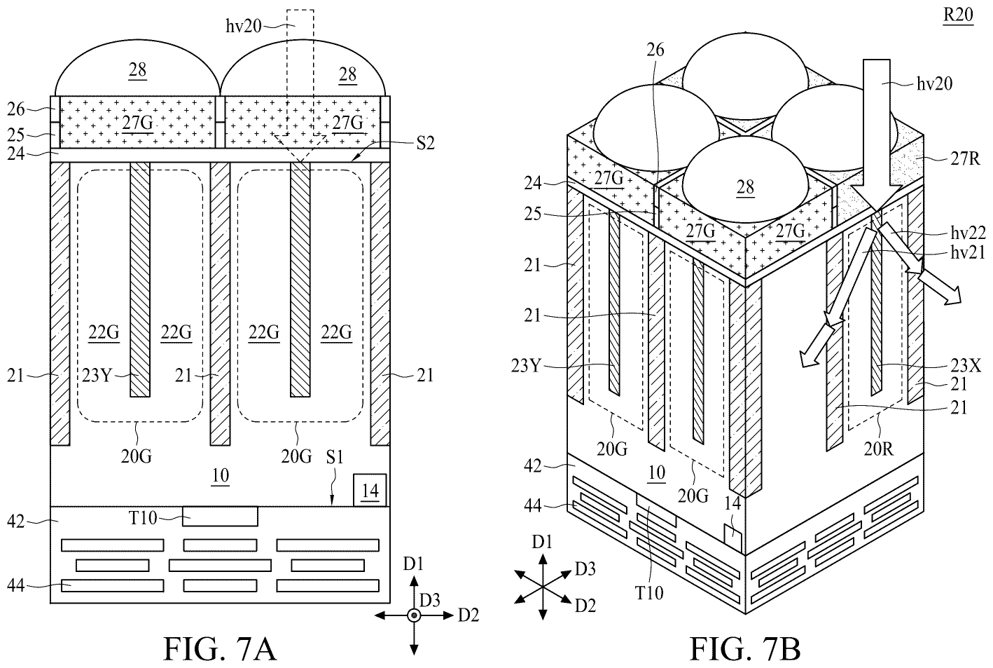

FIG. 7A is a schematic cross-sectional view of the portion R20 along a line DD′ in FIG. 4. FIG. 7B is a schematic perspective view of the portion R20 in FIG. 7A. Similar to the principle discussed above in reference to FIG. 3, when an incident light beam hv20 passes through the microlens 28, the red filter 27R and the anti-reflection layer 24, the incident light beam hv20 is split into at least two red light beams hv21 and hv22 by the first isolation member 23X. The red light beams hv21 and hv22 may penetrate neighboring photodiode regions 22G in the green pixel region 20G on opposite sides of the isolation structure 21. Therefore, portions of the green pixel region 20G accepting the additional red light beams (such as hv21 and hv22) will appear brighter. Referring to FIG. 4, a portion of the green pixel unit 120G at the bottom of the portion R20 (near the arrow) will appear brighter than the rest portion of the green pixel unit 120G.

The image sensing structure 110 includes both the first isolation members 23X and the second isolation members 23Y. Compared with the isolation member 23Y in the portion R10, the first isolation member 23X in the portion R20 has been “rotated” 90 degrees. As such, in each of the green pixel units 120G, two green pixel regions 20G accept the red light beams coming from neighboring red pixel regions 20R, as shown by the arrows in FIG. 4. Therefore, all the green pixel units 120G have substantially a same average brightness (i.e., half bright and half dark). A brightness uniformity of pixels of the image sensing structure 110 is thus improved. In some embodiments, the image sensing structure 110 has a better color performance when all the green pixel units 120G have the same average brightness compared with a design that some of the green pixel units 120G are physically bright and the other of the green pixel units 120G are physically dark.

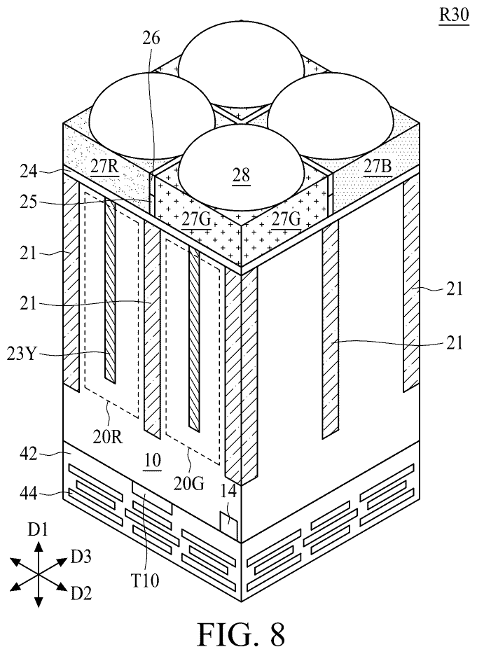

FIGS. 8 to 10 are schematic perspective views of various portions R30, R40 and R50 of FIG. 4. Referring to FIGS. 4 and 8, the portion R30 includes one red pixel region 20R, two green pixel regions 20G and one blue pixel region 20B adjacent to each other and separated by two isolation structures 21 perpendicular to each other. The portion R30 includes four second isolation members 23Y extending along the second direction D2 and no first isolation member 23X extending along the first direction D1. The second isolation members 23Y are disposed in the red pixel regions 20R, 20G and 20B.

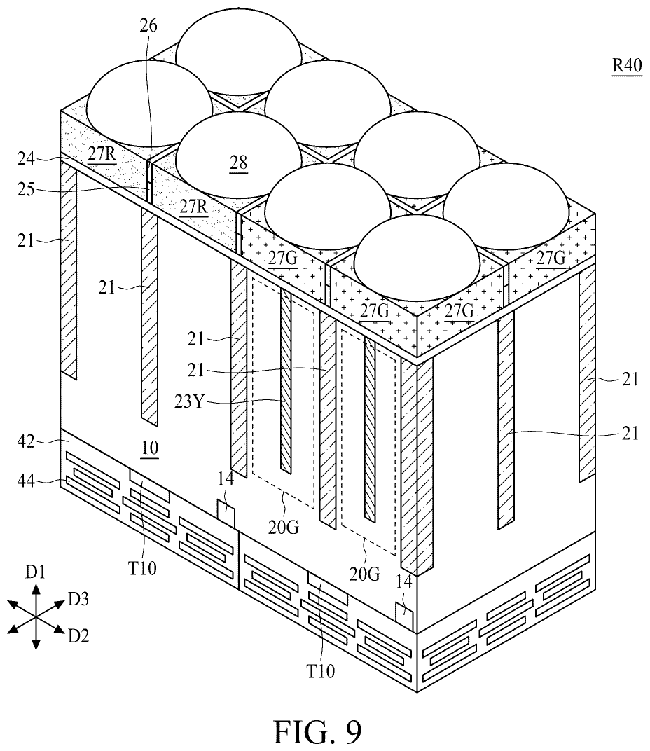

Referring to FIGS. 4 and 9, the portion R40 includes one red pixel unit 120R and one green pixel unit 120G adjacent to each other and separated by one isolation structure 21. The portion R40 includes four isolation member 23X extending along the first direction D1 and four isolation member 23Y extending along the second direction D2.

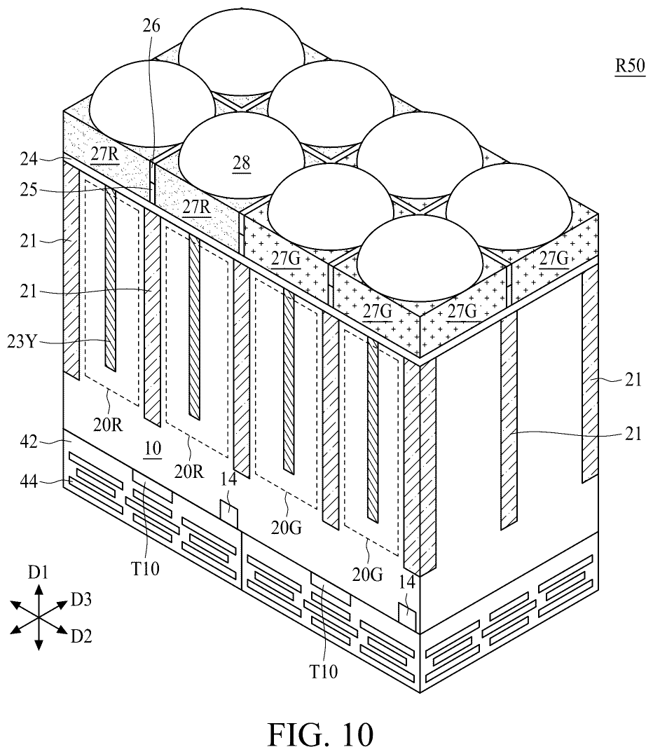

Referring to FIGS. 4 and 10, the portion R50 includes one red pixel unit 120R and one green pixel unit 120G adjacent to each other and separated by one isolation structure 21. The portion R50 is similar to the portion R40, except that in the portion R40, the first isolation members 23X are disposed in the red pixel unit 120R and the second isolation members 23Y are disposed in the green pixel unit 120G, while in the portion R50, the first isolation members 23X are disposed in the green pixel unit 120G and the second isolation members 23Y are disposed in the red pixel unit 120R.

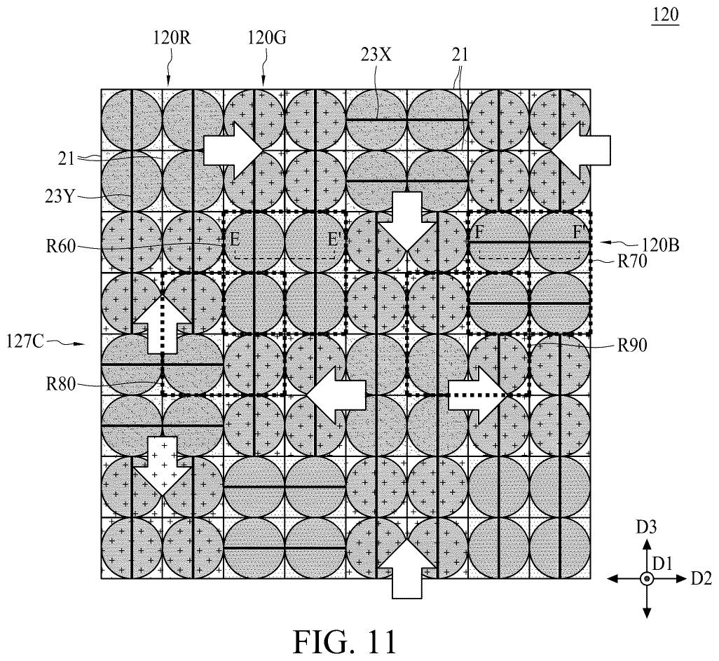

FIG. 11 is a schematic top view showing a CFA 127C of another image sensing structure 120. The image sensing structure 120 is similar to the image sensing structure 100 or 110, except the image sensing structure 120 has different orientations of isolation members. In the image sensing structure 120, all the green pixel units 120G have substantially a same average brightness because two green pixel regions 20G in each green pixel unit 120G accept red light beams coming from neighboring red pixel regions 20R, as shown in FIG. 11 by arrows. A brightness uniformity of pixels of the image sensing structure 120 is thus improved.

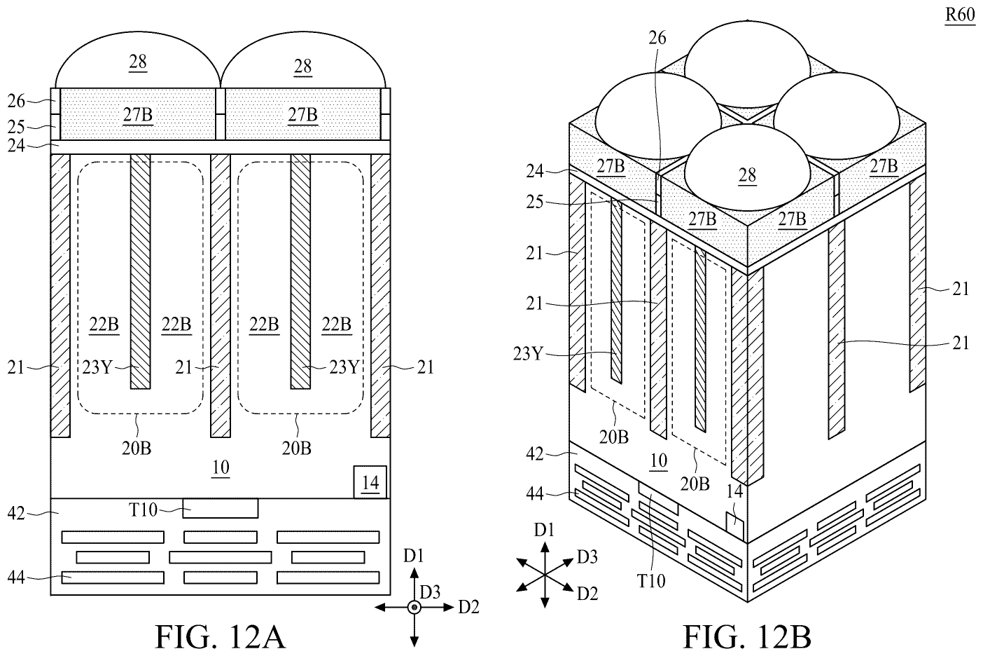

FIG. 12A is a schematic cross-sectional view of a portion R60 along a line EE′ in FIG. 11. FIG. 12B is a schematic perspective view of the portion R60 in FIG. 12A. The portion R60 is a blue pixel unit 120B including four blue pixel regions 20B adjacent to each other and separated by two isolation structures 21 perpendicular to each other. In some embodiments, the portion R60 includes four second isolation members 23Y extending along the second direction D2. Each isolation member 23Y is disposed between two photodiode regions 22B, as shown in FIG. 12A or 12B. The isolation member 23Y separates two photodiode regions 22B within the blue pixel region 20B. Therefore, there are eight photodiode regions 22B in the portion R60 (the blue pixel unit 120B).

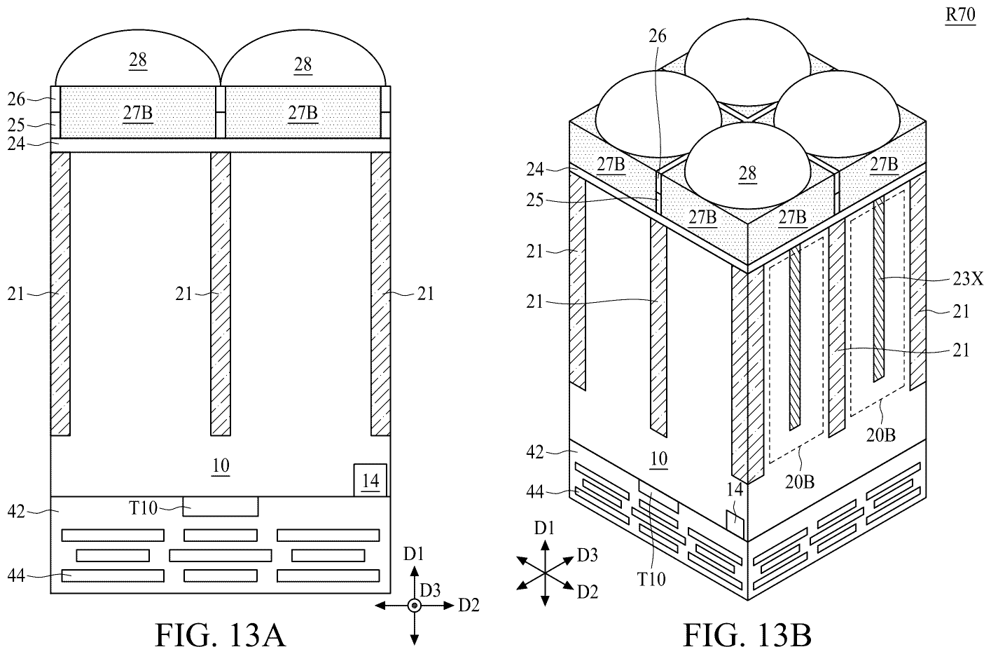

FIG. 13A is a schematic cross-sectional view of a portion R70 along a line FF′ in FIG. 11. FIG. 13B is a schematic perspective view of the portion R70 in FIG. 13A. The portion R70 is another blue pixel unit 120B similar to the portion R60, except the portion R70 includes four first isolation members 23X extending along the first direction D1. Each first isolation member 23X is disposed between two photodiode regions 22B within the blue pixel region 20B. Compared to the second isolation members 23Y in the portion R60, the first isolation members 23X in the portion R70 have been “rotated” 90 degrees. Therefore, not only can the isolation member in the red pixel unit 120R be rotated, but the isolation member in the blue pixel unit 120B can also be rotated.

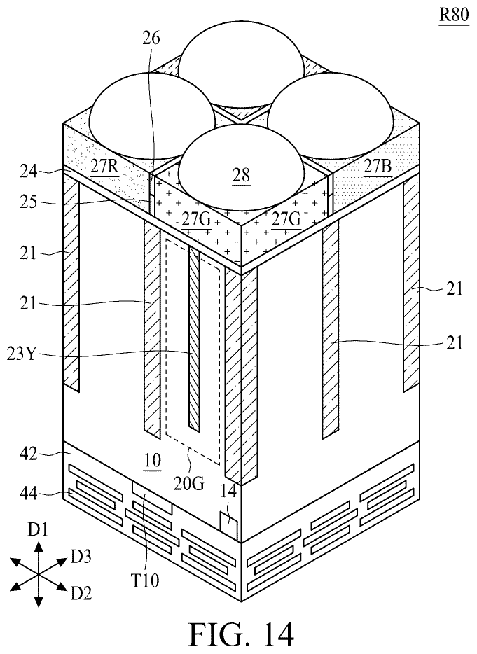

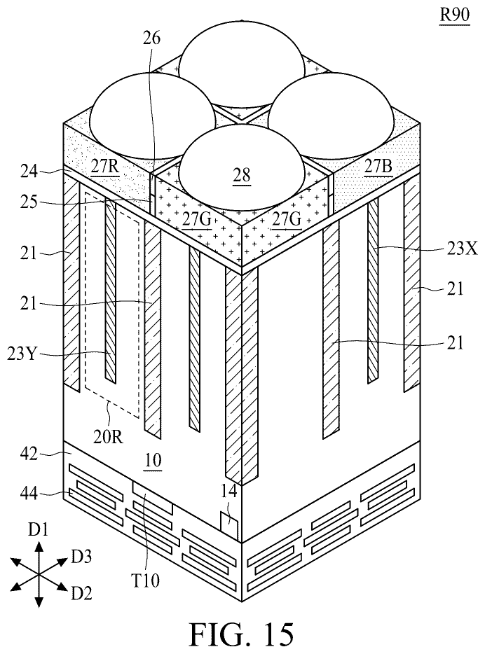

FIGS. 14 and 15 are schematic perspective views of portions R80 and R90 of FIG. 11. Referring to FIGS. 11 and 14, the portion R80 includes one red pixel region 20R, two green pixel regions 20G and one blue pixel region 20B adjacent to each other and separated by two isolation structures 21 perpendicular to each other. The portion R80 includes one first isolation member 23X extending along the first direction D1 and three second isolation members 23Y extending along the second direction D2. The first isolation member 23X is disposed in the red pixel region 20R, and the second isolation members 23Y are disposed in the green pixel regions 20G and the blue pixel region 20B.

Referring to FIGS. 11 and 15, the portion R90 includes one red pixel region 20R, two green pixel regions 20G and one blue pixel region 20B adjacent to each other and separated by two isolation structures 21 perpendicular to each other. The portion R90 includes one first isolation member 23X extending along the first direction D1 and three second isolation members 23Y extending along the second direction D2. The first isolation member 23X is disposed in the blue pixel region 20B, and the second isolation members 23Y are disposed in the red pixel region 20R and the green pixel regions 20G.

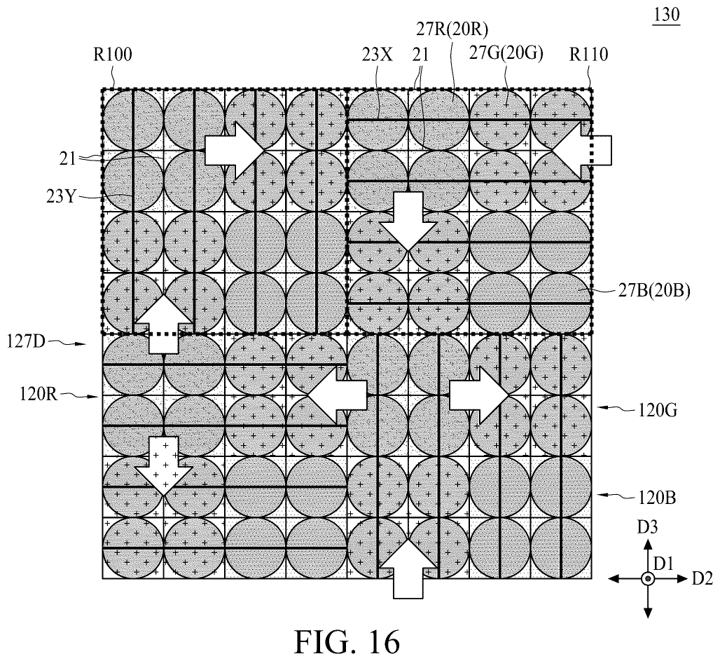

FIG. 16 is a schematic top view showing a CFA 127D of another image sensing structure 130. The image sensing structure 130 is similar to the image sensing structure 100, 110 or 120, except the image sensing structure 130 has different orientations of isolation members. In some embodiments, the image sensing structure 130 includes a portion R100 and a portion R110, each of which includes one red pixel unit 120R, two green pixel units 120G and one blue pixel unit 120B separated by the isolation structure 21. The portion R100 includes multiple second isolation members 23Y extending along the second direction D2 and no first isolation member 23X, while the portion R110 includes multiple first isolation members 23X extending along the first direction D1 and no isolation member 23Y. Compared to the second isolation members 23Y in the portion R100, the first isolation members 23X in the portion R110 have been “rotated” 90 degrees. In the image sensing structure 130, all the green pixel units 120G have substantially a same average brightness because two green pixel regions 20G in each green pixel unit 120G accept red light beams coming from neighboring red pixel regions 20R, as shown in FIG. 16 by arrows. A brightness uniformity of pixels of the image sensing structure 130 is thus improved.

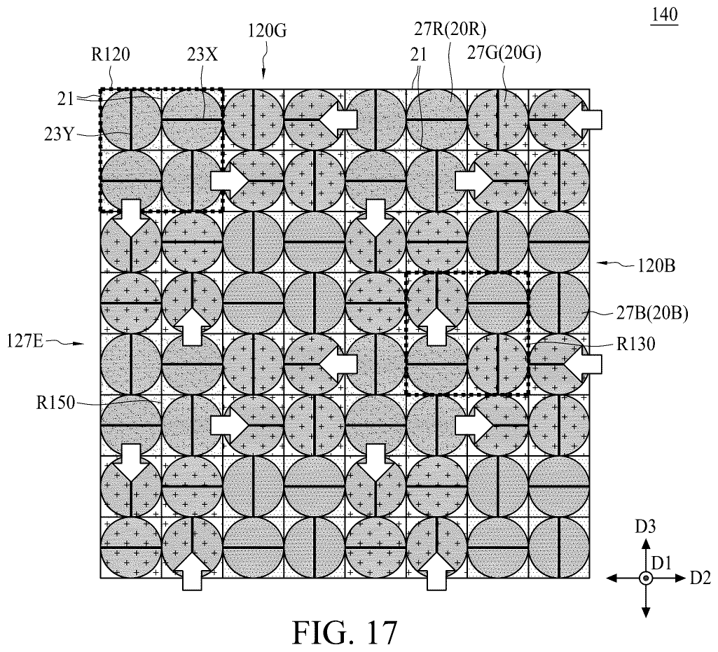

FIG. 17 is a schematic top view showing a CFA 127E of another image sensing structure 140. The image sensing structure 140 is similar to the image sensing structure 100, 110, 120 or 130 except the image sensing structure 140 has different orientations of isolation members. The image sensing structure 140 includes multiple red pixel units 120R, multiple green pixel units 120G and multiple blue pixel units 120B. In some embodiments, multiple first isolation members 23X extending along the first direction D1 and multiple second isolation members 23Y extending along the second direction D2 are disposed in each of the red pixel units 120R, the green pixel units 120G and the blue pixel units 120B. The first isolation members 23X and the second isolation members 23Y may be alternately arranged. In some embodiments, each of the red pixel units 120R, the green pixel units 120G and the blue pixel units 120B includes 50% first isolation members 23X and 50% second isolation members 23Y. That is, half of the isolation members in each pixel unit are rotated 90 degrees, and another half of the isolation members are not rotated.

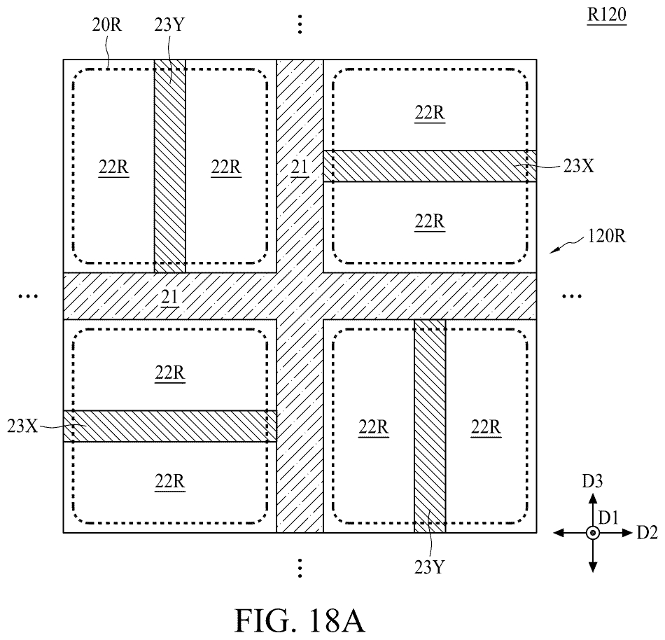

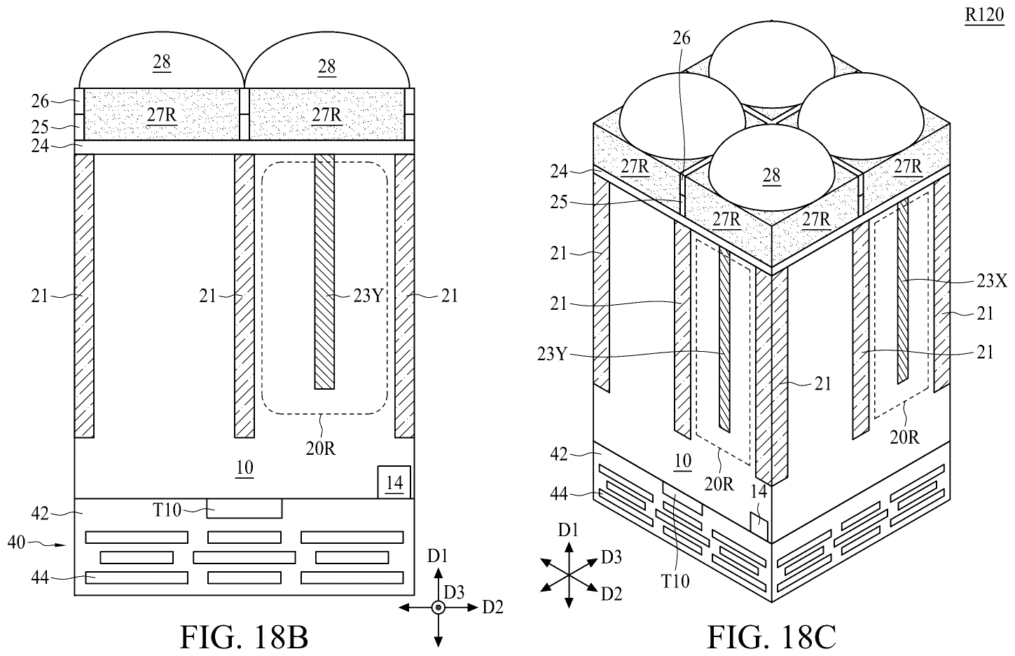

FIG. 18A is an enlarged view of a portion R120 of the image sensing structure 140 of FIG. 17. FIGS. 18B and 18C are schematic cross-sectional and perspective views of the portion R120 of FIG. 18A. Referring to FIG. 18A, the portion R120 is a red pixel unit 120R including four red pixel regions 20R adjacent to each other and separated by two isolation structures 21 perpendicular to each other. In some embodiments, the red pixel unit 120R includes two first isolation members 23X extending along the first direction D1 and two second isolation members 23Y extending along the second direction D2. In some embodiments, the two first isolation members 23X are connected to a same isolation structure 21, and the two second isolation members 23Y are connected to another isolation structure 21.

From the top view of FIG. 18A, the two first isolation members 23X are positioned diagonally opposite to each other, and the two second isolation members 23Y are positioned diagonally opposite to each other. As seen in FIG. 18A, in the upper left red pixel region 20R or the lower right red pixel region 20R, the two photodiode regions 22R are separated to left and right by the in-pixel DTI 23Y. That is, the two photodiode regions 22R are arranged along the first direction D1. As seen in FIG. 18A, in the upper right red pixel region 20R or the lower left red pixel region 20R, the two photodiode regions 22R are separated to front and back by the first isolation member 23X. That is, the pair of photodiode regions 22R are arranged along the second direction D2. FIGS. 18B and 18C illustrate the first isolation members 23X, the second isolation members 23Y and the isolation structures 21 embedded in the substrate 10 and extending along specific directions in the substrate 10.

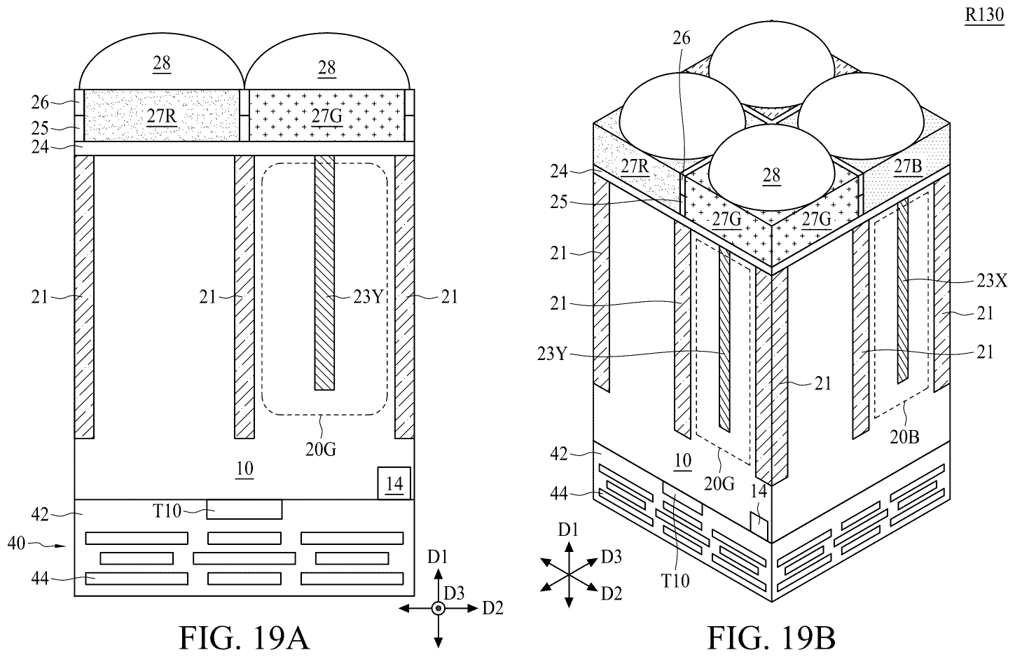

FIGS. 19A and 19B are schematic cross-sectional and perspective views of the portion R130 of the image sensing structure 140 of FIG. 17. Referring to FIGS. 17, 19A and 19B, the portion R130 includes one red pixel region 20R, two green pixel regions 20G and one blue pixel region 20B adjacent to each other and separated by two isolation structures 21 perpendicular to each other. The portion R130 includes one first isolation member 23X in the red pixel region 20R, one first isolation member 23X in the blue pixel region 20B and two first isolation members 23X respectively disposed in the green pixel regions 20G. The first isolation members 23X, the second isolation members 23Y and the isolation structures 21 are embedded in the substrate 10 and extend along specific directions in the substrate 10.

In the image sensing structure 140, all the green pixel units 120G have substantially a same average brightness because two green pixel regions 20G in each green pixel unit 120G accept red light beams coming from neighboring red pixel regions 20R, as shown in FIG. 17 by arrows. A brightness uniformity of pixels of the image sensing structure 140 is thus improved.

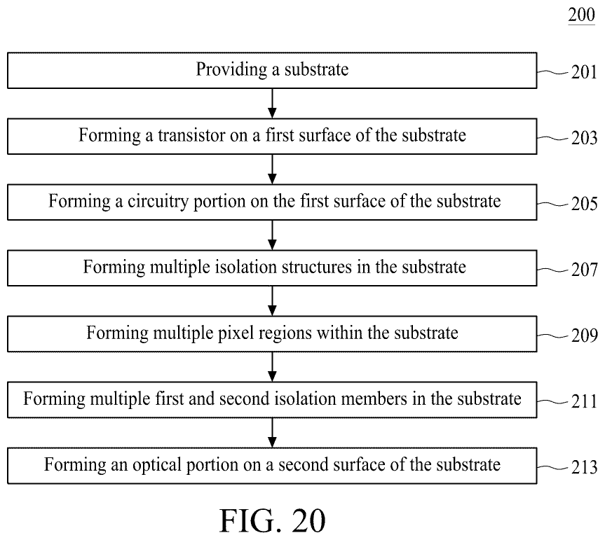

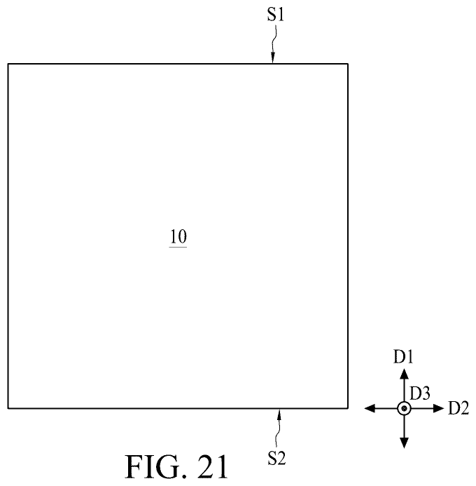

FIG. 20 is a flow diagram showing a method 200 for forming an image sensing structure 110. FIGS. 21 to 27 are schematic cross-sectional or top views illustrating sequential operations of the method 200 in FIG. 20. Operations 201, 203, 205, 207, 209 and 211 are used to form a pixel portion P2 connected to a circuitry portion P3.

For forming the pixel portion P2, in operation 201 of FIG. 20, a substrate 10 is provided, as shown in FIG. 21. The substrate 10 has a first surface S1 (or a front side S1) and a second surface S2 (or a back side S2) opposite to the first surface S1. The substrate 10 includes any type of semiconductor body such as a silicon (Si) wafer, a silicon-germanium (SiGe) wafer, a silicon-on-insulator (SOI) substrate, or the like. Although not shown, the substrate 10 includes one or more semiconductor layers and/or epitaxial layers formed thereon. In some embodiments, the substrate 10 is doped with p-type impurities and thus forms a p-type substrate 10.

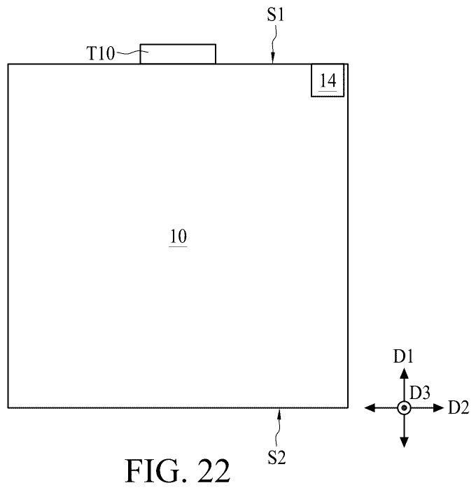

In operation 203 of FIG. 20, a transistor T10 is formed on the first surface S1 of the substrate 10, as shown in FIG. 22. The transistor T10 includes a gate structure and a source/drain structure, which may be formed using suitable methods such as photolithography, etching, epitaxy, implantation or deposition. In some embodiments, the transistor T10 includes a transfer transistor serving as a transfer gate, a reset transistor serving as a reset gate, a source follower transistor serving as a source follower gate (an amplification gate), and a selection transistor serving as a selection gate. In some embodiments, a floating node (or a floating diffusion region) 14 is formed within the substrate 10 and proximal to the first surface S1. The floating node 14 is formed as a high implant (e.g., N+ implant) in the substrate 10. The floating node 14 is electrically connected to the source follower transistor and/or the selection transistor.

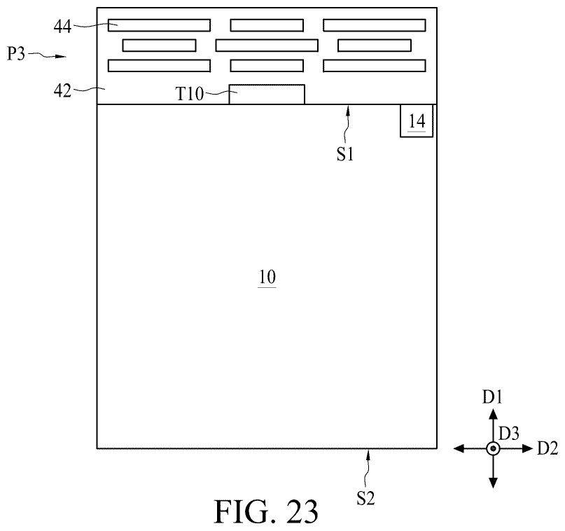

In operation 205 of FIG. 20, the circuitry portion P3 (or an interconnect portion P3) is formed on the first surface S1 of the substrate 10, as shown in FIG. 23. The circuitry portion P3 includes one or more interlayer dielectric (ILD) layers 42 and multiple conductive lines 44. The circuitry portion P3 can be formed using suitable methods such as photolithography, etching, deposition, electroplating or planarization. The ILD layer 42 may be formed of oxide or another suitable material. The ILD layer 42 may be formed of one or more of a low-k dielectric layer (i.e., a dielectric material with a dielectric constant less than about 3.9), an ultra low-k dielectric layer, or an oxide (e.g., silicon oxide). The conductive lines 44 can be formed of copper (Cu), cobalt (Co), aluminum (Al), silver (Ag), gold (Au), tungsten (W), the like, or a combination thereof. The conductive lines 44 are interconnected by conductive vias (not shown) and embedded in the ILD layer 42. The transistor T10 is covered and surrounded by the ILD layer 42. The circuitry portion P3 is electrically connected to the transistor T10.

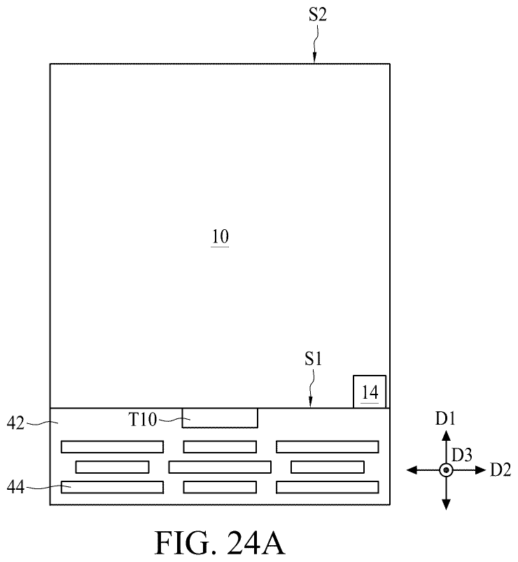

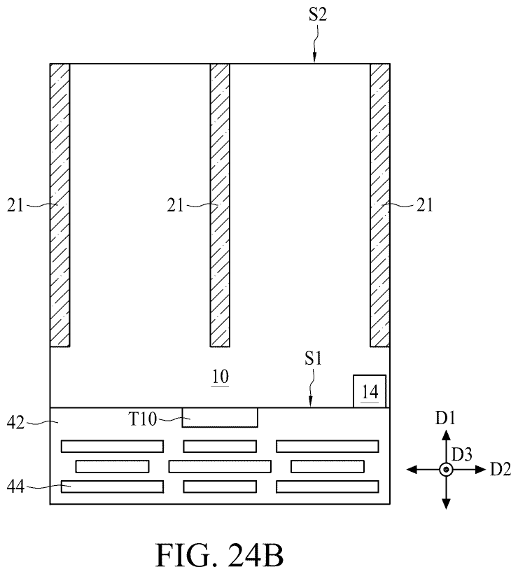

In operation 207 of FIG. 20, multiple isolation structures 21 are formed in the substrate 10, as shown in FIGS. 24A and 24B. Referring to FIG. 24A, the substrate 10 is flipped with the second surface S2 facing upward. Referring to FIG. 24B, although not specifically illustrated, photolithographic or etching operations are used to form multiple trenches extending from the second surface S2 of the substrate 10 to a predetermined depth of the substrate 10. A dielectric material is used to fill the trenches using a deposition operation. The dielectric material includes, for example, silicon oxide (SiO), silicon nitride (SiN), aluminum oxide (AlO), tantalum oxide (TaO), hafnium oxide (HfO), hafnium silicon oxide (HfSiO), hafnium aluminum oxide (HfAlO), hafnium tantalum oxide (HfTaO), or a combination thereof.

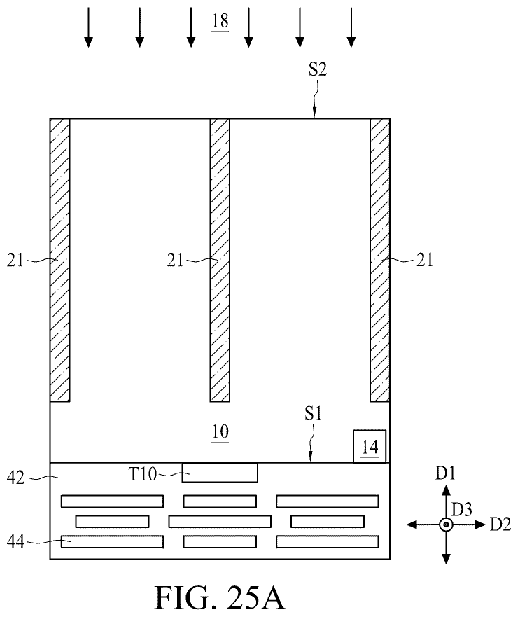

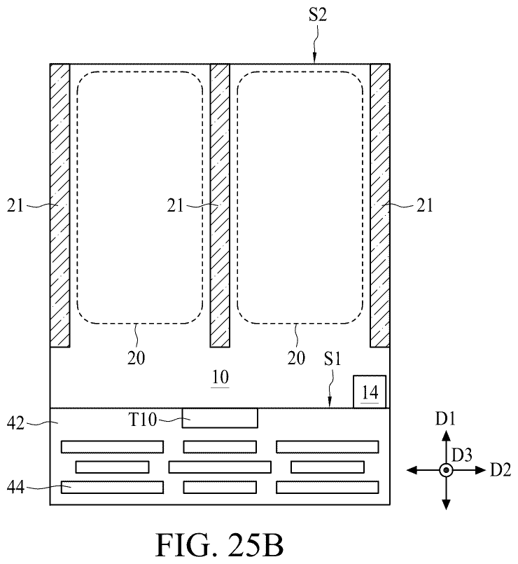

In operation 209 of FIG. 20, multiple pixel regions 20 are formed within the substrate 10, as shown in FIGS. 25A and 25B. Referring to FIG. 25A, an implantation operation is used to dope n-type impurities 18 into the substrate 10. Referring to FIG. 25B, the substrate 10 doped with the n-type impurities 18 to form the pixel regions 20. The pixel region 20 includes a P-N junction formed between the un-doped substrate 10 (which is p-type) and the doped substrate 10 (which is n-type). The P-N junction may form a photodiode. The pixel regions 20 are separated by the isolation structures 21.

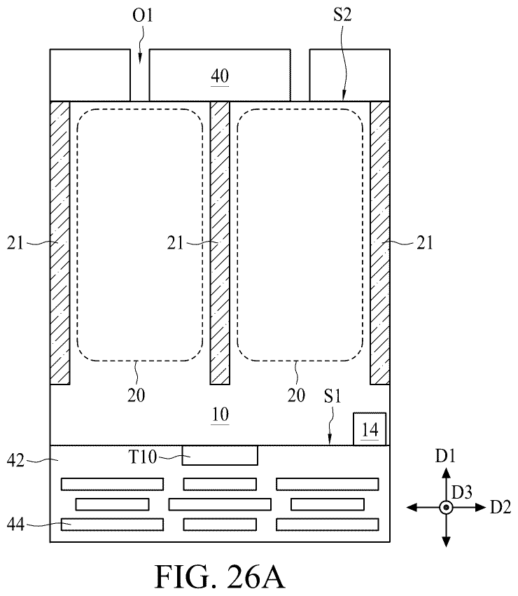

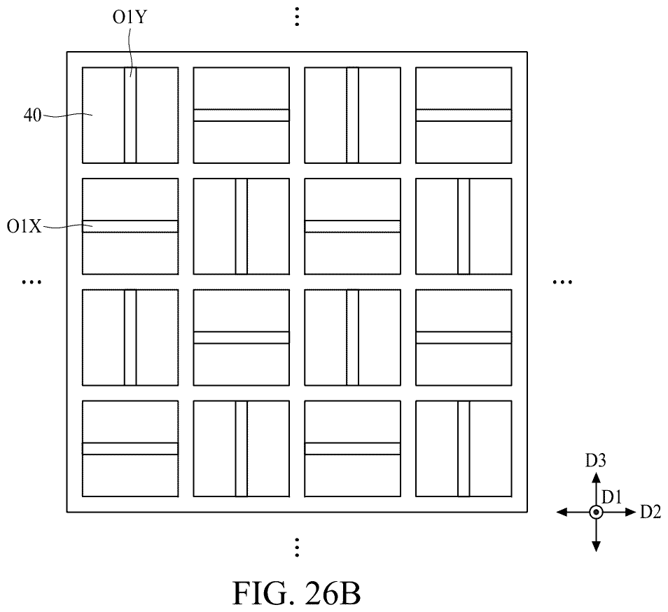

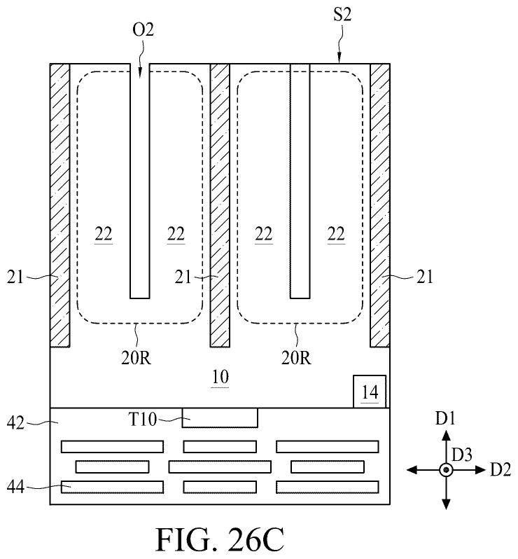

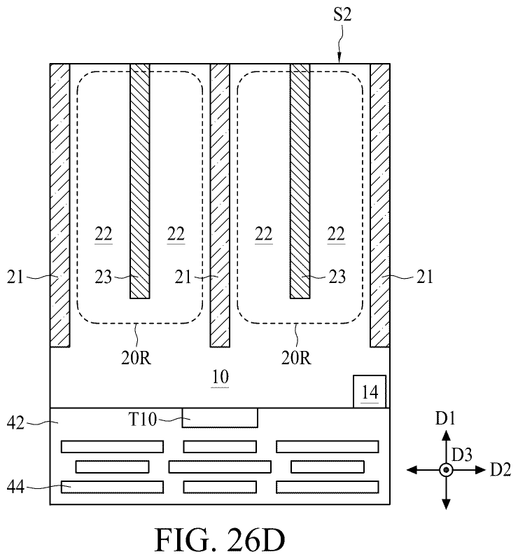

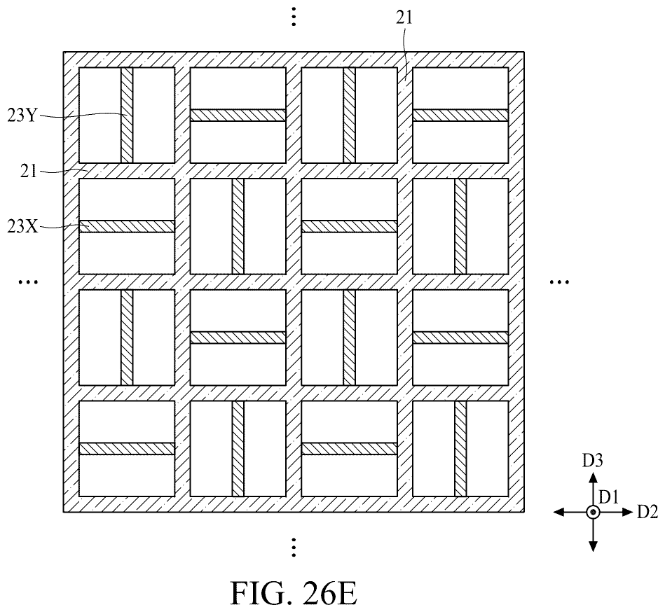

In operation 211 of FIG. 20, multiple first isolation members 23X and second isolation members 23Y are formed in the substrate 10, as shown in FIGS. 26A to 26E. Referring to FIG. 26A, a photoresist pattern 40 is formed on the substrate 10 using a photomask. The photoresist pattern 40 includes multiple openings O1 exposing portions of the second surface S2 corresponding to the pixel regions 20.

Referring to FIG. 26B, FIG. 26B is a schematic top view of FIG. 26A. In some embodiments, the openings O1 have a strip shape. In some embodiments, the openings O1 include first openings O1X extending along the second direction D2 and second openings O1Y extending along the third direction D3. In some embodiments, the first opening O1X is substantially orthogonal to the second opening O1Y.

Referring to FIG. 26C, an etching operation is used to remove portions of the substrate 10 using the photoresist pattern 40 as an etching mask. The photoresist pattern 40 is then removed. As a result, multiple trenches O2 are formed in the substrate 10. The trenches O2 extend from the second surface S2 of the substrate 10 to a predetermined depth of the substrate 10.

Referring to FIG. 26D, a deposition operation is used to deposit a dielectric material into the trenches O2. The dielectric material includes, for example, silicon oxide (SiO), silicon nitride (SiN), aluminum oxide (AlO), tantalum oxide (TaO), hafnium oxide (HfO), hafnium silicon oxide (HfSiO), hafnium aluminum oxide (HfAlO), hafnium tantalum oxide (HaTaO), or a combination thereof. A planarization operation may be used to remove excess dielectric material. Therefore, the isolation members 23 are formed in the substrate 10. The isolation member 23 has a top surface coplanar with the second surface S2 of the substrate 10 or the isolation structure 21.

Referring to FIG. 26E, FIG. 26E is a schematic top view of the structure of FIG. 26D. In some embodiments, the isolation members 23 have a strip shape. In some embodiments, the isolation members 23 include first isolation members 23X extending along the second direction D2 and second isolation members 23Y extending along the third direction D3. In some embodiments, the first isolation members 23X and the second isolation members 23Y are connected to the isolation structures 21. Therefore, formation of the pixel portion P2 and the circuitry portion P3 is complete.

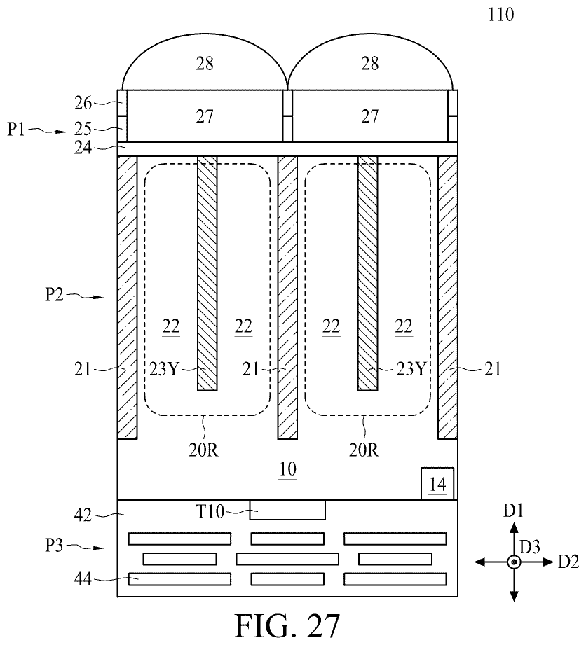

In operation 213 of FIG. 20, an optical portion P1 is formed on the second surface S2 of the substrate 10, as shown in FIG. 27. In some embodiments, the optical portion P1 includes an anti-reflection layer 24, multiple metal grids 25, one or more dielectric layers 26, multiple color filters 27, and multiple microlenses 28. The anti-reflection layer 24 is formed on the second surface S2 of the substrate 10. In some embodiments, the anti-reflection layer 24 is formed of oxide, nitride, a high-k dielectric material such as aluminum oxide (AlO), tantalum oxide (TaO), hafnium oxide (HfO), hafnium silicon oxide (HfSiO), hafnium aluminum oxide (HfAlO), hafnium tantalum oxide (HfTaO), or a combination thereof. The anti-reflection layer 24 may minimize light reflection and thus allow more light to reach the pixel regions 20.

In some embodiments, the metal grids 25 are formed on the anti-reflection layer 24 and aligned with the isolation structures 21, respectively. The metal grids 25 may be formed of tungsten (W), copper (Cu) or aluminum copper (AlCu). The metal grids 25 can be used to reduce optical interference of one pixel region 20 from an adjacent pixel region 20.

The color filters 27 are formed on the anti-reflection layer 24 and near to the metal grids 25. Adjacent color filters 27 are separated by one metal grid 25. Space over the metal grids 25 may be filled with the dielectric layer 26 made of oxide. The color filters 27 are separated from the substrate 10 or the pixel region 20 by the anti-reflection layer 24.

In some embodiments, each color filter 27 is aligned with a corresponding pixel region 20. The color filter 27 is formed over two photodiode regions 22 and an isolation member 23 between the two photodiode regions 22. Such arrangement can increase radiation of incident light onto the pixel region 20. The color filter 27 is used to allow light or radiation having wavelengths within a specific range to pass. For example, a color filter 27 used to transmit incident light with a wavelength between about 620 nanometers (nm) and about 750 nm (i.e., red light) is referred to as a red filter 27R. A color filter 27 used to transmit incident light with a wavelength between about 495 nm and about 570 nm (i.e., green light) is referred to as a green filter 27G. A color filter 27 used to transmit incident light with a wavelength between about 450 nm and about 495 nm (i.e., blue light) is referred to as a blue filter 27B.

In some embodiments, the microlens 28 is formed on the color filter 27 and portions of the dielectric layer 26. The microlens 28 has a curved surface (or convex surface) that directs an incoming light and facilitates condensation of the incident light. The microlens 28 is aligned with the color filter 27 and the pixel region 20. Such arrangement can increase radiation of the incident light on the pixel region 20. Since the photodiode regions 22 are formed in pairs in a single pixel region 20, a color filter 27 is formed over two photodiode regions 22, and a microlens 28 is formed over two photodiode regions 22. As a result, the formation of the image sensing structure 110 is complete.

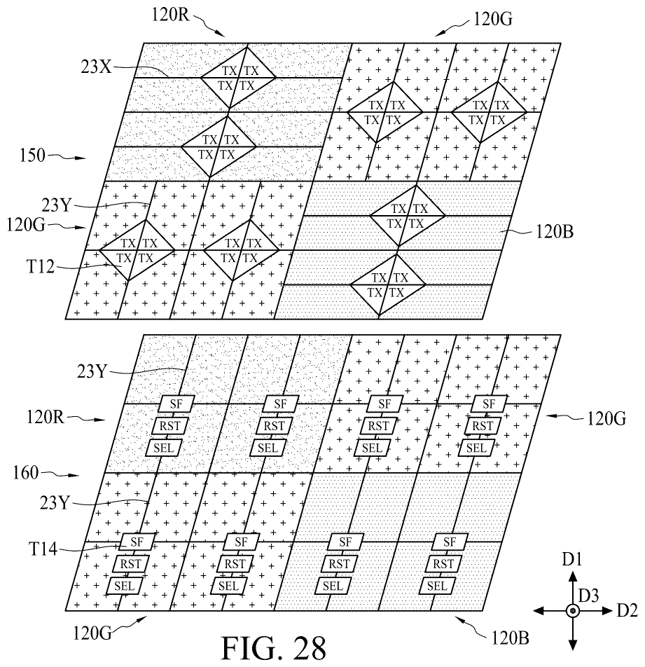

FIG. 28 is a schematic perspective view illustrating a combination of two image sensing structures 150 and 160. In some embodiments, the image sensing structure 150 is a portion of an image sensing device formed on a first wafer, and the image sensing structure 160 is a portion of an image sensing device formed on a second wafer. In some embodiments, the image sensing structure 150 includes multiple first isolation members 23X and second isolation members 23Y. For example, the first isolation members 23X may be disposed in the red pixel unit 120R and the blue pixel unit 120B, but the present disclosure is not limited thereto. In some embodiments, the image sensing structure 160 includes multiple second isolation members 23Y. Compared with the image sensing structure 160, half of the second isolation members 23Y in the image sensing structure 150 are rotated 90 degrees to form the first isolation members 23X.

In some embodiments, the image sensing structure 150 includes multiple first transistors T12 symmetrically arranged with each other. The first transistors T12 include transfer (TX) transistors or transfer gates. In some embodiments, the first transistors T12 are disposed below and at both sides of one first isolation member 23X. In some embodiments, the first transistors T12 are disposed below and at both sides of one second isolation member 23Y. In some embodiments, the image sensing structure 160 includes multiple second transistors T14 disposed adjacent to the second isolation members 23Y. An arrangement of the second transistors T14 may be parallel to an extension direction of the second isolation member 23Y. The second transistors T14 include reset (RST) transistors, source follower (SF) transistors, row selection (SEL) transistors, or the like. In some embodiments, the image sensing structure 150 is aligned with and bonded to the image sensing structure 160. In such embodiments, the first transistors T12 may be electrically connected to the second transistors T14. With such design, layout of transistors and wirings of image sensing structures can be simplified. In addition, uneven brightness of pixels can also be solved.

One aspect of the present disclosure provides an image sensing structure. The image sensing structure includes: a first pixel, including a first photodiode, a second photodiode and a first isolation member disposed between the first photodiode and the second photodiode and extending along a first direction; and a second pixel, disposed adjacent to the first pixel and including a third photodiode, a fourth photodiode and a second isolation member disposed between the third photodiode and the fourth photodiode and extending along a second direction substantially perpendicular to the first direction.

One aspect of the present disclosure provides another image sensing structure. The image sensing structure includes: a first sensing member including a plurality of first pixels adjacent to and separated from each other, wherein each of the plurality of first pixels includes a first photodiode, a second photodiode and a first isolation member disposed between the first photodiode and the second diode; and a second sensing member, adjacent to the first sensing member and including a plurality of second pixels adjacent to and separated from each other, wherein each of the plurality of second pixels includes a third photodiode, a fourth photodiode and a second isolation member disposed between the third photodiode and the fourth photodiode, wherein at least one of the first isolation members extends along a first direction, and at least one of the second isolation members extends along a second direction substantially perpendicular to the first direction.

Another aspect of the present disclosure provides a method of forming an image sensing structure. The method includes: providing a substrate having a first surface and a second surface opposite to the first surface; forming a first photodiode and a second photodiode in the substrate; forming a third photodiode and a fourth photodiode in the substrate; forming a first isolation member extending within the substrate and between the first photodiode and the second photodiode; and forming a second isolation member adjacent to the first isolation member and extending within the substrate and between the third photodiode and the fourth photodiode, wherein the first isolation member extends along a first direction, and the second isolation member extends along a second direction substantially perpendicular to the first direction.

The foregoing outlines features of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods or steps, presently existing or later to be developed, that perform substantially the same function or achieve substantially the same result as the corresponding embodiments described herein be utilized according to the present invention. Accordingly, the appended claims are intended to include within their scope such processes, machines, manufacture, compositions of matter, means, methods and steps.

1. An image sensing structure, comprising:
a first pixel, including a first photodiode, a second photodiode, and a first isolation member, the first isolation member disposed between the first photodiode and the second photodiode and extending along a first direction; and
a second pixel, disposed adjacent to the first pixel and including a third photodiode, a fourth photodiode, and a second isolation member, the second isolation member disposed between the third photodiode and the fourth photodiode and extending along a second direction substantially perpendicular to the first direction.

2. The image sensing structure of claim 1, wherein the first pixel includes a first color filter disposed over the first photodiode, the second photodiode, and the first isolation member, and the second pixel includes a second color filter disposed over the third photodiode, the fourth photodiode, and the second isolation member.

3. The image sensing structure of claim 2, wherein the first color filter is a red filter, and the second color filter is a green filter or blue filter.

4. The image sensing structure of claim 2, wherein the first color filter is a red filter or blue filter, and the second color filter is a green filter.

5. The image sensing structure of claim 2, wherein the first color filter and the second color filter are red filters.

6. The image sensing structure of claim 1, further comprising a third isolation member disposed between the first pixel and the second pixel and extending along the second direction.

7. The image sensing structure of claim 6, wherein the third isolation member is disposed between the first photodiode and the third photodiode, and between the first photodiode and the fourth photodiode.

8. The image sensing structure of claim 6, wherein a thickness of the first isolation member and a thickness of the second isolation member are respectively less than a thickness of the third isolation member.

9. The image sensing structure of claim 1, wherein
a second image sensing structure is bonded to the image sensing structure,
the image sensing structure includes a first transistor, and
the second image sensing structure includes a second transistor electrically connected to the first transistor.

10. The image sensing structure of claim 9, wherein
the first transistor includes a transfer transistor, and
the second transistor includes a reset transistor, a source follower transistor or a row selection transistor.

11. An image sensing structure, comprising:
a first sensing member including a plurality of first pixels adjacent to and separated from each other, wherein each of the plurality of first pixels includes a first photodiode, a second photodiode, and a first isolation member, the first isolation member disposed between the first photodiode and the second photodiode; and
a second sensing member, adjacent to the first sensing member and including a plurality of second pixels adjacent to and separated from each other, wherein each of the plurality of second pixels includes a third photodiode, a fourth photodiode, and a second isolation member, the second isolation member disposed between the third photodiode and the fourth photodiode,
wherein at least one of the first isolation members extends along a first direction, and at least one of the second isolation members extends along a second direction substantially perpendicular to the first direction.

12. The image sensing structure of claim 11, wherein all of the first isolation members extend along the first direction, and all of the second isolation members extend along the second direction.

13. The image sensing structure of claim 11, wherein each of the plurality of first pixels is a red pixel, and each of the plurality of second pixels is a green pixel or a blue pixel.

14. The image sensing structure of claim 11, wherein each of the plurality of first pixels is a red pixel or a blue pixel, and each of the plurality of second pixels is a green pixel.

15. The image sensing structure of claim 11, wherein the plurality of first pixels include a first red pixel, a first green pixel, and a first blue pixel, and the plurality of second pixels include a second red pixel, a second green pixel, and a second blue pixel.

16. A method of forming an image sensing structure, comprising:
providing a substrate having a first surface and a second surface opposite to the first surface;
forming a first photodiode and a second photodiode in the substrate;
forming a third photodiode and a fourth photodiode in the substrate;
forming a first isolation member extending within the substrate and between the first photodiode and the second photodiode; and
forming a second isolation member adjacent to the first isolation member and extending within the substrate and between the third photodiode and the fourth photodiode,
wherein the first isolation member extends along a first direction, and the second isolation member extends along a second direction substantially perpendicular to the first direction.

17. The method of claim 16, wherein the first photodiode and the second photodiode extend along the first direction, and the third photodiode and the fourth photodiode extend along the second direction, and the first photodiode, the second photodiode, the third photodiode, and the fourth photodiode are formed by ion implantation operation.

18. The method of claim 16, wherein the formation of the first photodiode and the second photodiode and the formation of the third photodiode and the fourth photodiode are performed prior to the formation of the first isolation member and prior to the formation of the second isolation member.

19. The method of claim 16, wherein the formation of the first isolation member includes removing a first portion of the substrate from the first surface toward the second surface to form a first trench and filling the first trench by a dielectric material, the formation of the second isolation member includes removing a second portion of the substrate from the first surface toward the second surface to form a second trench and filling the second trench by the dielectric material.

20. The method of claim 19, wherein the first trench is substantially perpendicular to the second trench.
